(19) United States
(12) Patent Application Publication
(10) Pub. No.: US 2006/0115954 A1
(43) Pub. Date: Jun. 1, 2006

(54) Methods of manufacturing a capacitor and a semiconductor device

(76) Inventors: Woo-Seok Shim, Seoul (KR); Young-Wook Park, Suwon-si (KR); Jung-Hyeon Lee, Yongin-si (KR); Kwang-Sub Yoon, Seoul (KR); Chul-Ho Kim, Seoul (KR); Tae-Jin Park, Cheongju-si (KR)

Correspondence Address: MILLS & ONELLO LLP, ELEVEN BEACON STREET, SUITE 605, BOSTON, MA, 02108, US

(21) Appl. No.: 11/265,937

(22) Filed: Nov. 3, 2005

(30) Foreign Application Priority Data
Nov. 29, 2004 (KR) 10-2004-0098538

(51) Int. Cl. H01L 21/20; H01L 21/8242

(52) U.S. Cl. 438/396; 438/253

(57) ABSTRACT

In methods of manufacturing a capacitor and a semiconductor device, a mold layer is formed on a substrate having a contact plug. The mold layer includes an opening exposing the contact plug. A conductive layer is formed on the contact plug, an inner sidewall of the opening and the mold layer. A photoresist pattern is formed to substantially fill the opening. A cylindrical lower electrode is formed by partially removing the conductive layer. The mold layer is selectively removed while the photoresist pattern prevents damage to the lower electrode, the contact plug and the substrate. The photoresist pattern is removed, and then a dielectric layer and an upper electrode are sequentially formed on the lower electrode. Damage to the lower electrode and the contact plug are effectively prevented due to the presence of the photoresist pattern during selective removal of the mold layer.

### CROSS-REFERENCE TO RELATED APPLICATIONS

This application claims priority under 35 USC § 119 to Korean Patent Application No. 2004-98538 filed on Nov. 29, 2004, the contents of which are herein incorporated by reference in its entirety.

### BACKGROUND OF THE INVENTION

1. Field of the Invention

Example embodiments of the present invention relate to methods of manufacturing a capacitor and a semiconductor device. More particularly, example embodiments of the present invention relate to a method of manufacturing a capacitor having a lower electrode including metal and a method of manufacturing a semiconductor device such as a DRAM device including such a capacitor.

2. Description of the Related Art

Semiconductor devices continue to be developed to have higher response speed, larger storage capacity and lower power consumption as information processing systems enjoy widespread use. Semiconductor devices are typically categorized into volatile semiconductor memory devices and non-volatile semiconductor memory devices. Volatile semiconductor memory devices include dynamic random access memory (DRAM) devices and static random access memory (SRAM) devices. In general, a volatile semiconductor memory device, such as a DRAM device, includes a capacitor and a switching element such as a transistor.

A polysilicon-insulator-polysilicon (PIP) capacitor has been widely employed for semiconductor memory devices. The PIP capacitor is readily fabricated because polysilicon is relatively stable at high temperatures, and a manufacturing technology, such as a chemical vapor deposition (CVD) process, has become highly developed. However, electrical characteristics of the PIP capacitor can vary in accordance with applied voltage. Particularly, since a lower electrode and an upper electrode of the PIP capacitor are made of polysilicon, depletion layers can be formed between the upper electrode and an insulation layer, and between the insulation layer and the lower electrode. When the depletion layers are generated in the PIP capacitor, a dielectric layer of the PIP capacitor can have a relatively increased thickness, causing deterioration of the capacitance of the PIP capacitor. In particular, when the PIP capacitor is employed for a highly integrated semiconductor device having a design rule of below about 90 nm, the semiconductor device may not have a desired capacitance.

Considering the above-mentioned disadvantages of the PIP capacitor, a metal-insulator-metal (MIM) capacitor has been developed.

In a method of manufacturing a conventional MIM capacitor, an insulating interlayer is formed on a substrate, and then a contact plug is formed through the insulating interlayer. The contact plug is typically formed using doped polysilicon because metal may melt or diffuse in subsequent processes performed at relatively high temperatures. A cylindrical lower electrode of metal is formed on the contact plug. Here, a galvanic coupling may be generated between the lower electrode formed of metal and the contact plug formed of polysilicon because galvanic couplings are generally created between two different conductive layers or patterns. When a galvanic coupling is formed between two different conductive layers or patterns, one of the conductive layers or patterns is especially susceptible to erosion. In the case where the galvanic coupling is generated between the lower electrode of metal and the contact plug of polysilicon, polysilicon in the contact plug may be rapidly eroded by chemicals used in subsequent etching processes for forming the MIM capacitor. As a result, a void may be generated between the contact plug and the lower electrode because the contact plug can become rapidly etched in the etching processes for forming the lower electrode.

Meanwhile, a cylindrical lower electrode of a capacitor is typically formed using a chemical mechanical polishing (CMP) process. When the cylindrical lower electrode is formed by the CMP process, an additional layer such as a sacrificial layer is formed to protect the cylindrical lower electrode. However, the CMP process may require a relatively long time and also process conditions of the CMP process may not be easily controlled. Further, the process time of the CMP process can be longer when the cylindrical lower electrode is formed using metal, because an abrasive used in the CMP process has a relatively lower polishing rate as compared to that of metal.

In view of the above, a method of manufacturing a cylindrical lower electrode of a capacitor without a CMP process has been developed. This method has been disclosed in Korean Laid-Open Patent Publication No. 2004-046704, Korean Laid-Open Patent Publication No. 2004-001886 and Japanese Laid-Open Patent Publication No. 2001-053251. According to the conventional methods of manufacturing the cylindrical lower electrode, a photoresist film is formed in an opening for forming the cylindrical lower electrode, and then the cylindrical lower electrode is formed by an etching process.

However, the conventional methods of manufacturing the lower electrode only provide a lower electrode having a concave structure of which only the interior portion is used as an effective area of the capacitor. Although the lower electrode having the concave structure may have structural stability, the effective area of the capacitor is substantially smaller than that of a capacitor including a lower electrode of a fully cylindrical shape. Additionally, the conventional methods of manufacturing the lower electrode disclose only doped polysilicon employed for the lower electrode, without metal. When the lower electrode is formed using doped polysilicon, a depletion layer may be generated between the lower electrode and a dielectric layer so that the dielectric layer will have a more increased theoretical thickness. Hence, such a form of lower electrode is not suitable for use in a capacitor that is to be included in a highly integrated semiconductor device requiring a high storage capacitance.

### SUMMARY OF THE INVENTION

Example embodiments of the present invention provide a method of manufacturing a capacitor having an improved capacitance while preventing damage to a contact plug, a lower electrode and/or underlying layers of the capacitor.

Example embodiments of the present invention further provide a method of manufacturing a semiconductor device including the capacitor.

In one aspect, the present invention is directed to a method of manufacturing a capacitor. In the method of manufacturing the capacitor, a mold layer is formed on a substrate having a contact plug. The mold layer includes an opening exposing the contact plug. A conductive layer is formed on the contact plug, an inner sidewall of the opening and the mold layer. A photoresist pattern is formed to substantially fill the opening. A cylindrical lower electrode is formed by partially removing the conductive layer. The mold layer is selectively removed while the photoresist pattern prevents damage to the lower electrode, the contact plug and the substrate. After removing the photoresist pattern, a dielectric layer and an upper electrode are sequentially formed on the lower electrode.

In an example embodiment of the present invention, the conductive layer comprises a film selected from the group consisting of: a titanium film, a titanium nitride film; and a multi-layer structure that includes a titanium film and a titanium nitride film.

In an example embodiment of the present invention, the contact plug includes a conductive material different from that of the conductive layer. For example, the contact plug includes polysilicon doped with impurities.

In an example embodiment of the present invention, the photoresist pattern is formed by forming a photoresist film on the conductive layer that fills the opening, by exposing the photoresist film to a light by a blank exposure process, and by developing the photoresist film. The light is defocused relative to the photoresist film in the blank exposure process in order to selectively develop an upper portion of the photoresist film. The photoresist film can include a coloring agent to adjust a permeability of the light. The photoresist film can be thermally treated after forming the photoresist film.

In an example embodiment of the present invention, the lower electrode is formed by an etch back process.

In an example embodiment of the present invention, the photoresist pattern is formed by forming a photoresist film on the conductive layer to substantially fill the opening, and by partially removing the photoresist film.

In an example embodiment of the present invention, the mold layer is removed using a wet etching solution.

In an example embodiment of the present invention, the photoresist pattern is removed by an ashing process and/or a stripping process.

In an example embodiment of the present invention, an etch stop layer is formed on the substrate before forming the mold layer.

In an example embodiment of the present invention, the conductive layer is formed by a process selected from the group consisting of: a chemical vapor deposition (CVD) process, a cyclic CVD process and an atomic layer deposition (ALD) process.

In another aspect, the present invention is directed to a method of manufacturing a semiconductor device. In the method of manufacturing the semiconductor device such as a DRAM device, a transistor is formed on a substrate, and then a first insulating interlayer is formed on the substrate. The first insulating interlayer includes a first pad electrode and a second pad electrode electrically connected to source/drain regions of the transistor. A second insulating interlayer is formed on the first insulating interlayer. The second insulating interlayer includes a bit line electrically connected to the first pad electrode. A third insulating interlayer is formed on the second insulating interlayer. The third insulating interlayer includes a contact plug electrically connected to the second pad electrode. A mold layer is formed on the third insulating interlayer. The mold layer includes an opening exposing the contact plug. A conductive layer is formed on the contact plug, an inner sidewall of the opening and the mold layer. A photoresist pattern is formed to substantially fill the opening, and a cylindrical lower electrode is formed by partially removing the conductive layer. The mold layer is selectively removed while the photoresist pattern prevents damage to the lower electrode and underlying structures. After removing the photoresist pattern, a dielectric layer is formed on the lower electrode and the third insulating interlayer. Then, an upper electrode is formed on the dielectric layer.

In an example embodiment of the present invention, an etch stop layer is formed on the third insulating interlayer before forming the mold layer.

According to the present invention, since an etching solution will not permeate into the lower electrode and a contact plug electrically connected to a lower electrode of a capacitor during selective removal of the mold layer, damage to the lower electrode and the contact plug is effectively prevented. As a result, the semiconductor device fabricated accordingly will have improved electrical characteristics and reliability with reduced likelihood of failure.

In addition, the lower electrode of the capacitor can be formed without a CMP process so that the time and cost associated with manufacturing a semiconductor device including the capacitor can be reduced. Further, the capacitor includes a lower electrode of conductive material such as metal so that the capacitor can have an enhanced capacitance value.

### BRIEF DESCRIPTION OF THE DRAWINGS

The above and other features and advantages of the present invention will become more apparent by describing in detailed example embodiments thereof with reference to the accompanying drawings, in which:

FIGS. 1 to 10 are cross-sectional views illustrating a method of manufacturing a semiconductor device in accordance with an example embodiment of the present invention; and

FIGS. 11 and 12 are cross-sectional views illustrating a method of manufacturing a semiconductor device in accordance with an example embodiment of the present invention.

### DETAILED DESCRIPTION OF EMBODIMENTS OF THE INVENTION

The present invention is described more fully hereinafter with reference to the accompanying drawings, in which embodiments of the present invention are shown. The present invention may, however, be embodied in many different forms and should not be construed as limited to the embodiments set forth herein. Rather, these embodiments are provided so that this disclosure will be thorough and complete. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. The terminology used herein is for the purpose of describing particular embodiments only and is not intended to be limiting of the invention.

Embodiments of the present invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

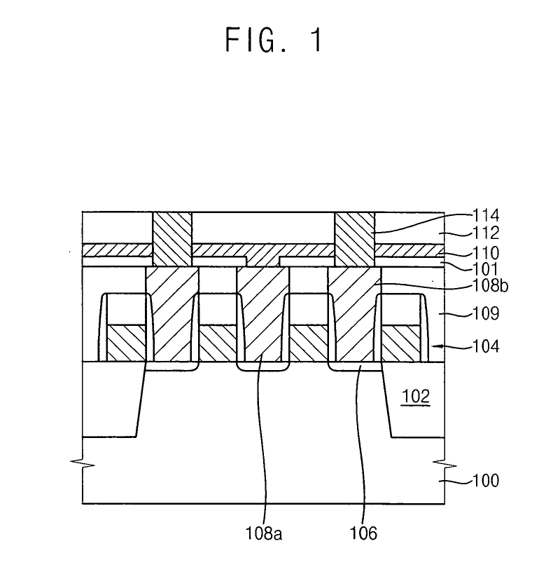

FIGS. 1 to 10 are cross-sectional views illustrating a method of manufacturing a semiconductor device in accordance with an example embodiment of the present invention.

Referring to FIG. 1, an isolation layer 102 is formed on a semiconductor substrate 100 to define an active region and a field region. The isolation layer 102 may be formed, for example, by an isolation process such as a shallow trench isolation (STI) process. The isolation layer 102 may include an oxide such as silicon oxide.

Gate structures 104 are formed on the semiconductor substrate 100. Each of the gate structures 104 includes a gate insulation layer pattern, a gate electrode, a gate mask and a gate spacer sequentially formed on the substrate 100.

Source/drain regions 106 are formed at upper portions of the substrate 100 adjacent to the gate structure 104. The source/drain regions 106 may be formed, for example, by an ion implantation process. The source/drain regions 106 complete formation of the transistors on the substrate 100.

A first insulating interlayer 109 is formed on the substrate 100 to cover the transistors. The first insulating interlayer 109 may be formed, for example, using an oxide such as silicon oxide. Additionally, the first insulating interlayer 109 may be formed by a chemical vapor deposition (CVD) process, a plasma enhanced chemical vapor deposition (PECVD) process, a high density plasma-chemical vapor deposition (HDP-CVD) process or an atomic layer deposition (ALD) process.

The first insulating interlayer 109 is partially etched to form first contact holes that expose the source/drain regions 106, respectively. After a first conductive layer is formed on the first insulating interlayer 109 to fill the first contact holes, the first conductive layer is partially removed to thereby form first and second pad electrodes 108a and 108b in the first contact holes. The first and the second pad electrodes 108a and 108b may be formed, for example, using a metal, a metal nitride, or polysilicon doped with impurities. For example, the first and the second pad electrodes 108a and 108b are formed using tungsten (W), tungsten nitride (WN), titanium (Ti), titanium nitride (TiN), aluminum (Al), aluminum nitride (AlN), tantalum (Ta), tantalum nitride (TaN), etc. The first pad electrode 108a is electrically contacted with a bit line 110, whereas the second pad electrode 108b is electrically connected to a capacitor.

A second insulating interlayer 101 is formed on the first insulating interlayer 109, the first pad electrode 108a and the second pad electrode 108b. The second insulating interlayer 101 may be formed using an oxide such as silicon oxide. Additionally, the second insulating interlayer 101 may be formed by a CVD process, a PECVD process, an HDP-CVD process or an ALD process.

The second insulating interlayer 101 is partially etched to form a second contact hole that exposes the first pad electrode 108a. A second conductive layer is formed on the second insulating interlayer 101 to fill up the second contact hole. The second conductive layer is patterned to thereby form the bit line 110 making contact with the first pad electrode 108a. The bit line 110 may be formed, for example, using a metal, a conductive metal nitride or polysilicon doped with impurities.

A third insulating interlayer 112 is formed on the bit line 110. The third insulating interlayer 112 may be formed using an oxide such as silicon oxide. The third insulating interlayer 112 may be formed by a CVD process, a PECVD process, an HDP-CVD process or an ALD process.

The third insulating interlayer 112 is partially etched to thereby form a third contact hole that exposes the second pad electrode 108b. In an example embodiment of the present invention, the third contact hole may have an upper portion substantially wider than a lower portion thereof.

After a third conductive layer is formed on the third insulating interlayer 112 to fill up the third contact hole, the third conductive layer is partially removed to form a contact plug 114 in the third contact hole. The contact plug 114 is formed, for example, using a metal, a metal nitride or polysilicon doped with impurities. The contact plug 114 electrically contacts the second pad electrode 108b.

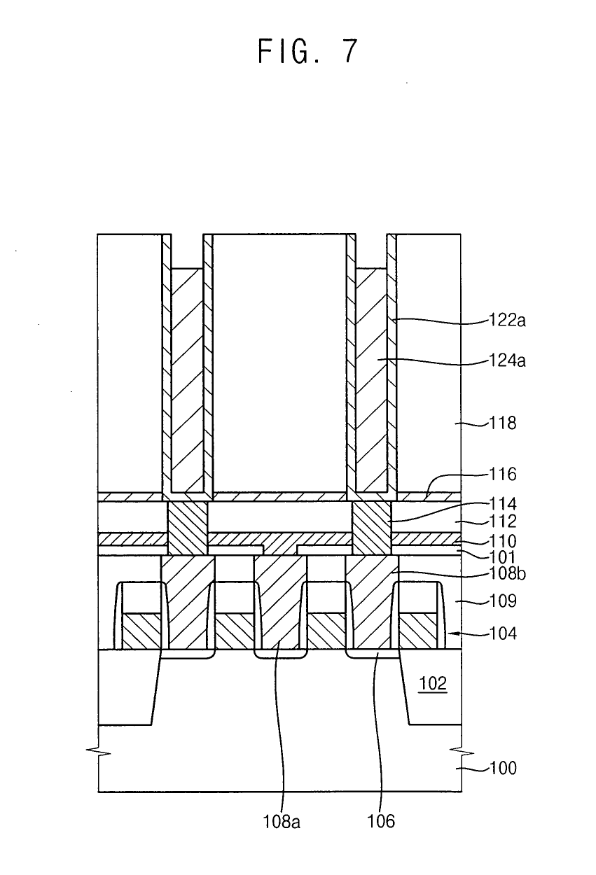

When the third contact hole has the upper portion wider than the lower portion, the contact plug 114 also has an upper portion substantially wider than a lower portion thereof in accordance with a shape of the third contact hole. In case that an upper width of the contact plug 114 is substantially wider than a lower width of the contact plug 114, a contact area between a lower electrode 122a (see FIG. 7) of the capacitor and the contact plug 114 may increase so that an alignment margin of a process for forming the lower 122a may be sufficiently ensured.

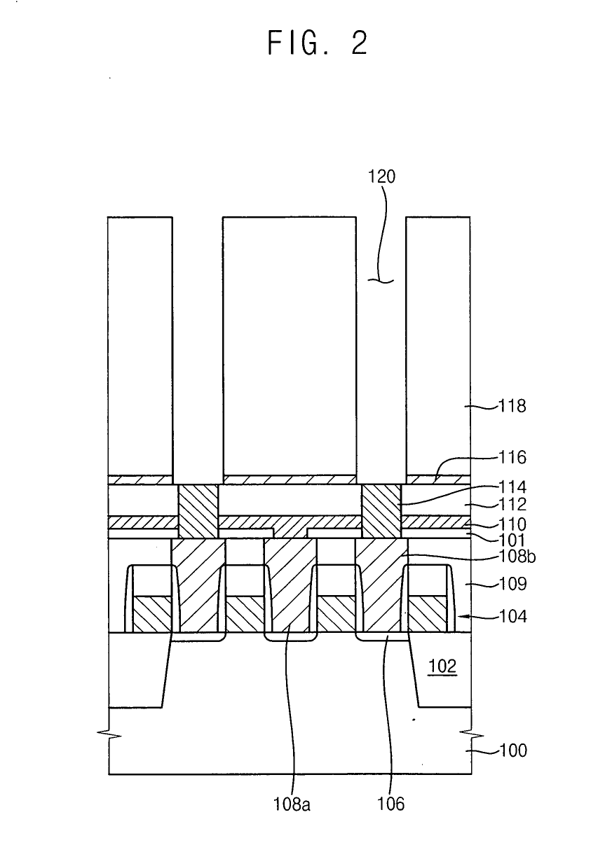

Referring to FIG. 2, an etch stop layer 116 is formed on the third insulating interlayer 112 and the contact plug 114. The etch stop layer 116 is formed using a material that has an etching selectivity relative to that of a mold layer 118. That is, the etch stop layer 116 may be formed using a material which is not etched with respect to an etching solution or an etching gas that is used for etching the mold layer 118. For example, the etch stop layer 116 is formed using a nitride such as silicon nitride.

The mold layer 118 is formed on the etch stop layer 116. The mold layer 118 may be formed, for example, using an oxide such as silicon oxide. For example, the mold layer 118 is formed using tetraethylorthosilicate (TEOS), HDP-CVD oxide, phosphosilicate glass (PSG), borophosphosilicate glass (BPSG), undoped silicate glass (USG), spin-on glass (SOG), etc. In one example embodiment of the present invention, the mold layer 118 may have a multi-layer structure that includes at least two of the above oxides. In another example embodiment of the present invention, the mold layer 118 may have a multi-layer structure that includes at least two oxides having different etching rates in order to form an opening 120 that has a stepped sidewall.

The mold layer 118 may have a thickness properly adjusted in accordance with a desired capacitance of the capacitor. In other words, the thickness of the mold layer 118 may be suitably varied in accordance with the desired height of the capacitor because the height of the capacitor will depend primarily on the thickness of the mold layer 118.

The mold layer 118 and the etch stop layer 116 are partially etched to thereby form the opening 120. The opening 120 exposes the contact plug 114 through the mold layer 118 and the etch stop layer 116. In an example embodiment of the present invention, when the opening 120 is formed through the mold layer 118 and the etch stop layer 116, the etch stop layer 116 may be over-etched so as to completely remove the etch stop layer 116 positioned on the contact plug 114. Thus, an upper portion of the contact plug 114 may be slightly etched to thereby form a recess at the upper portion of the contact plug 114. In other words, an indent may be formed at a central upper portion of the contact plug 114 after forming the opening 120.

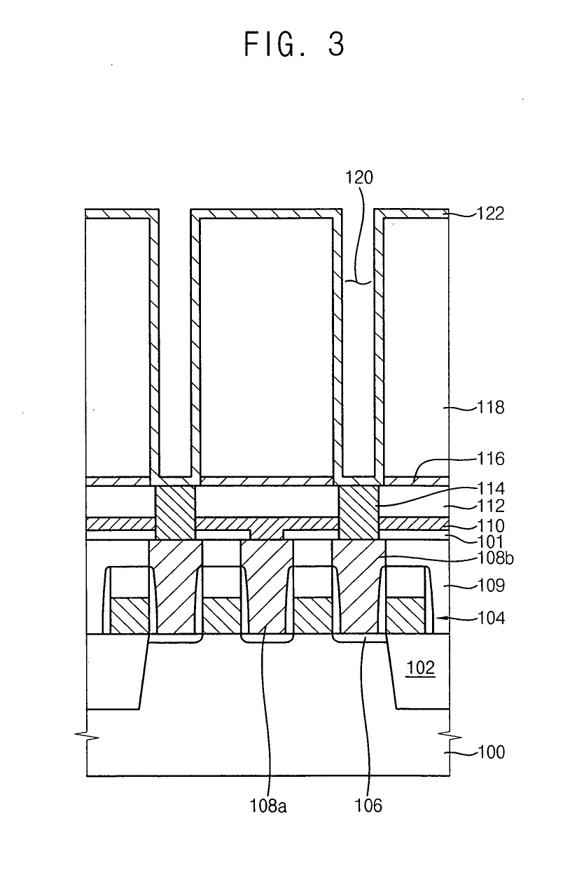

Referring to FIG. 3, a fourth conductive layer 122 is continuously formed on the contact plug 114, on the inner sidewalls of the opening 120 and on the mold layer 118. The fourth conductive layer 122 is formed using, for example, a metal or a metal nitride. For example, the fourth conductive layer 122 is formed using titanium, titanium nitride, aluminum, aluminum nitride, titanium aluminum nitride, tantalum, tantalum nitride, etc. Alternatively, the fourth conductive layer 122 may have a multi-layer structure that includes a titanium film and a titanium nitride film. Here, the titanium film serves as a barrier layer for preventing diffusion of metal atoms.

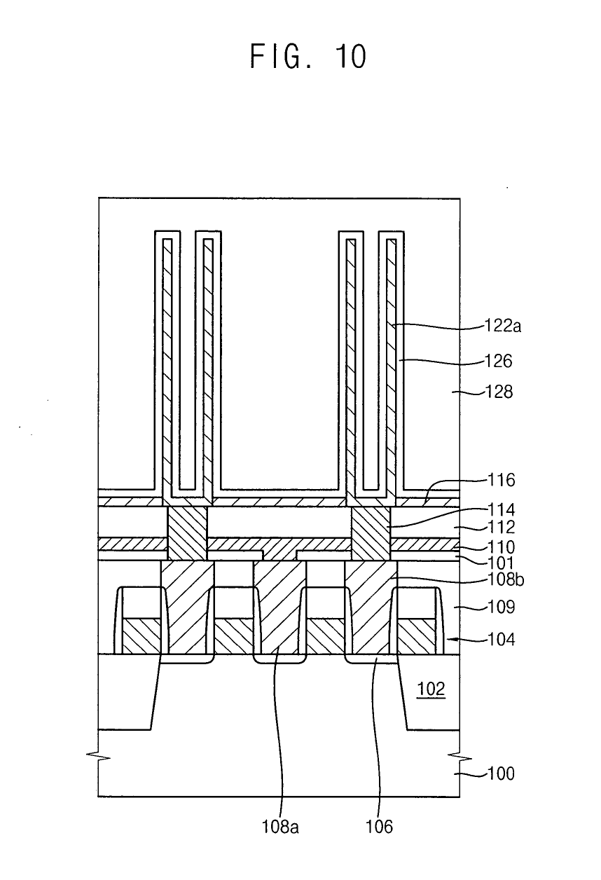

When the fourth conductive layer 122 is formed using metal or metal nitride instead of doped polysilicon, the capacitor may have an improved capacitance because a depletion layer will not be formed between the lower electrode 122a and a dielectric layer 126 (see FIG. 10).

Since the opening 120 has a relatively high aspect ratio, the fourth conductive layer 122 is formed to have good step coverage. In addition, the fourth conductive layer 122 has a relatively thin thickness so that the opening 120 is not filled with the fourth conductive layer 122. Thus, the fourth conductive layer 122 may be formed by a CVD process, an ALD process or a cyclic CVD process.

When the fourth conductive layer 122 is formed using metal or metal oxide, cracks or crystalline defects are easily generated in the fourth conductive layer 122 in comparison with the case where doped polysilicon is employed for the fourth conductive layer 122. In succeeding etching processes, chemicals included in etching solutions may easily permeate into the fourth conductive layer 122 through the cracks or the defects. Additionally, the chemicals will more easily permeate into the fourth conductive layer 122 through grain boundaries of particles included in the fourth conductive layer 122 when the fourth conductive layer 122 has a columnar crystalline structure.

Meanwhile, when the fourth conductive layer 122 includes a titanium/titanium nitride film formed by the CVD process, the resulting fourth conductive layer 122 will have a columnar crystalline structure. Additionally, cracks are generated in the fourth conductive layer 122 having the titanium/titanium nitride film when the fourth conductive layer 122 has a relatively thick thickness.

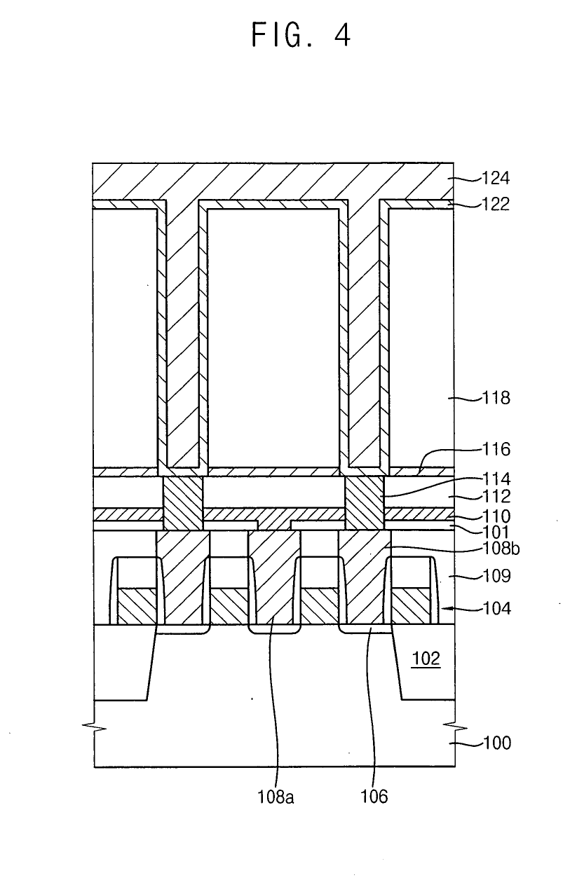

Referring to FIG. 4, a photoresist is coated on the fourth conductive layer 122. The photoresist may be coated, for example, by a spin coating process. In one example embodiment of the present invention, since an upper portion of the photoresist is exposed to light during a subsequent exposure process, process conditions of the exposure process for the photoresist may be easily controlled by selecting a suitable type of photoresist. In another example embodiment of the present invention, the photoresist may include a coloring agent for adjusting the permeability of the light irradiated on the photoresist in the exposure process.

The photoresist coated on the fourth conductive layer 122 is thermally treated to reflow the photoresist into and to fill up the opening 120. When the photoresist is thermally treated, the opening 120 is completely filled with the photoresist, forming a photoresist film 124.

In an example embodiment of the present invention, the capacitors are not formed in a peripheral region of the substrate 100, and thus the openings 120 are not positioned in the peripheral region of the substrate 100. Hence, a first portion of the photoresist film 124 in the peripheral region of the substrate 100 may have a height substantially higher than that of a second portion of the photoresist film 124 positioned in a cell region of the substrate 100.

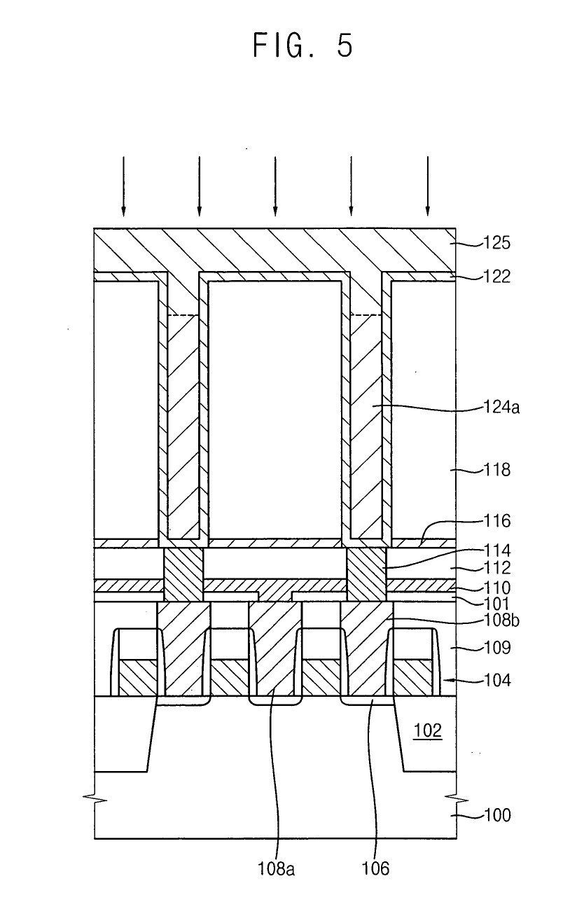

Referring to FIG. 5, the photoresist film 124 is exposed by a blank exposure process using the light indicated as arrows. In the blank exposure process, the photoresist film 124 is exposed to the light without using a reticle.

After the blank exposure process is performed on the photoresist film 124, a portion of the photoresist film 124 positioned at an upper portion of the opening 120 and over the mold layer 118 is sufficiently exposed to the light so that the first portion of the photoresist film 124 is converted into a water-soluble photoresist pattern 125. On the other hand, a portion of the photoresist film 124 positioned in the opening 120 is not exposed to the light. Hereinafter, the unexposed portion of the photoresist film 124 is referred to as a first photoresist pattern 124a, and the exposed portion of the photoresist film 124 is referred to as a second photoresist pattern 125. Additionally, in the blank exposure process, a light defocused relative to a surface of the photoresist film 124 may be advantageously used so that the portion of the photoresist film 124 in the opening 120 is not exposed.

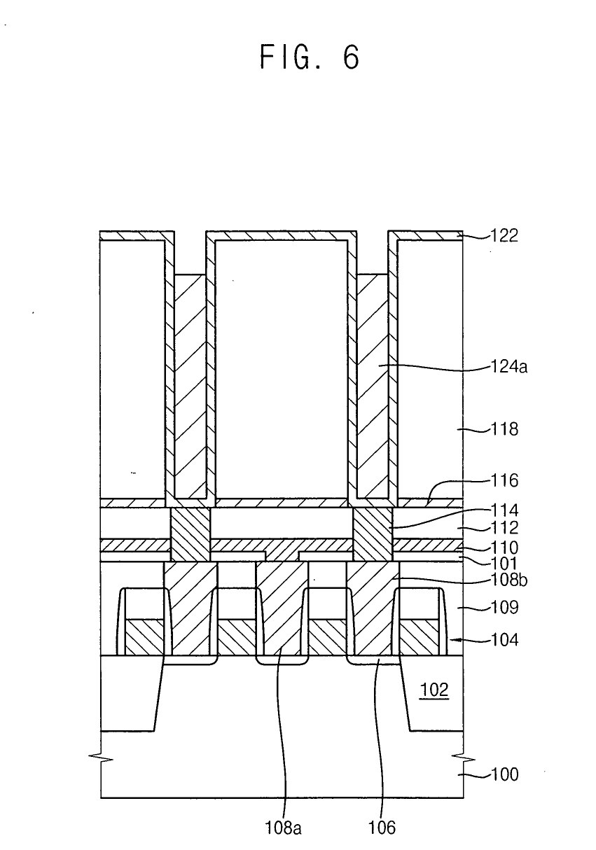

Referring to FIG. 6, the first and the second photoresist patterns 124a and 125 are developed to thereby remove the second photoresist pattern 125. Thus, the first photoresist pattern 124a remains in the opening 120. When a developing process is executed on the first and the second photoresist patterns 124a and 125, the first photoresist pattern 124a remains in the opening 120 whereas the water-soluble second photoresist pattern 125 is removed. Thus, the fourth conductive layer 122 on the mold layer 118 is exposed.

Referring to FIG. 7, the fourth conductive layer 122 is partially removed until the mold layer 118 is exposed. The fourth conductive layer 122 may be partially removed in a dry etching process. When the fourth conductive layer 122 is partially etched, the lower electrode 122a is formed in the opening 120. The lower electrode 122a may have a cylindrical shape. In particular, the lower electrode 122a is positioned on the sidewall of the opening 120, and the opening 120 is partially filled with the first photoresist pattern 124a. The lower electrode 122a makes electrical contact with the contact plug 114.

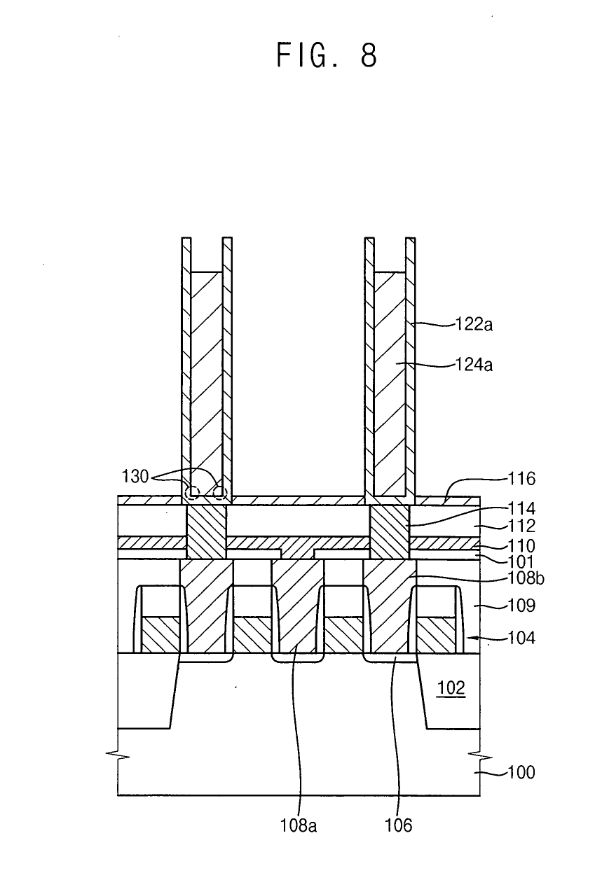

Referring to FIG. 8, the mold layer 118 is selectively removed whereas the first photoresist pattern 124a remains on the lower electrode 122a in the opening 120. The mold layer 118 may be removed, for example, by a wet etching process. In the wet etching process, the mold layer 118 may be etched using an etching solution containing hydrogen fluoride (HF), an etching solution containing ammonium hydroxide (NH₄OH), hydrogen peroxide (H₂O₂) and deionized water such as a standard cleaning 1 (SC-1) solution, or an etching solution containing ammonium fluoride (NH₄F), hydrogen fluoride and deionized water such as an LAL solution.

In the process for removing the mold layer 118, the etching solution may permeate into the contact plug 114 through cracks generated in the lower electrode 122a or grain boundaries of ingredients included in the lower electrode 122a. In particular, the etching solution may easily permeate into the contact plug 114 through lower edge portions 130 of the lower electrode 122a because most of the cracks or defects are usually generated at the lower edge portions 130 of the lower electrode 122a. However, since the first photoresist pattern 124a covers the lower electrode 122a including the lower edge portions, the etching solution does not permeate into the contact plug 114. That is, the first photoresist pattern 124a prevents the contact plug 114, the lower electrode 122a and/or the underlying layers from being damaged by the etching solution. As a result, semiconductor device failures, such as a DRAM device failures can be effectively prevented while preventing damage to the contact plug 114 and/or the lower electrode 122a.

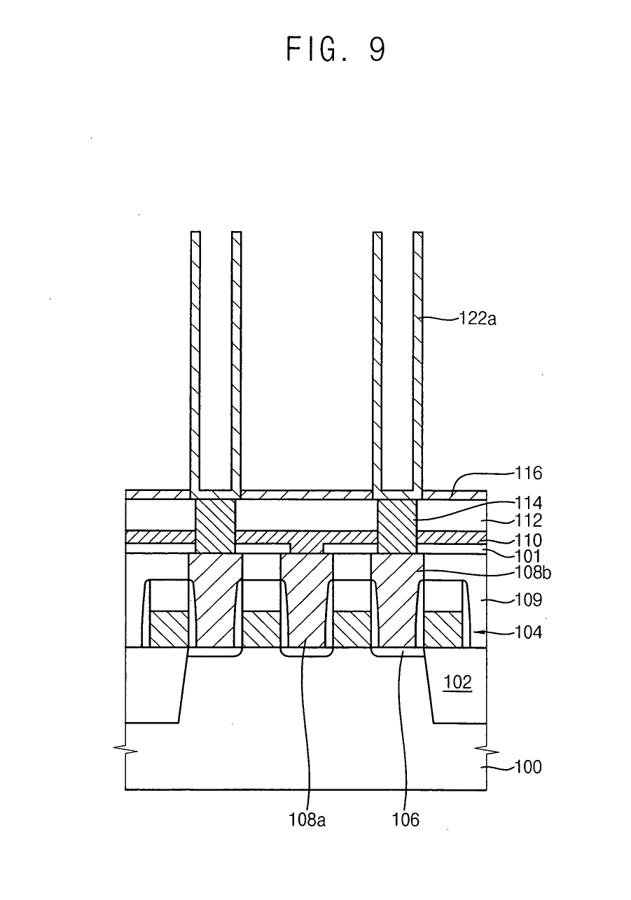

Referring to FIG. 9, the first photoresist pattern 124a is removed from the lower electrode 122a. The first photoresist pattern 124a may be removed by an ashing process and/or a stripping process. In the process for removing the first photoresist pattern 124a, the first photoresist pattern 124a including organic materials is removed without damage to the contact plug 114 and the lower electrode 122a.

When the mold layer 118 and the first photoresist pattern 124a are removed, the cylindrical lower electrode 122a is completely exposed. The exposed surface area of the lower electrode 122a may be an effective area of the capacitor so that the capacitor including the cylindrical lower electrode 122a can have a capacitance that is larger than that of the conventional capacitor including a concave lower electrode.

Referring to FIG. 10, a dielectric layer 126 is formed on the lower electrode 122a and the etch stop layer 116. The dielectric layer 126 is formed, for example, using a metal oxide that has a high dielectric constant. For example, the dielectric layer 126 is formed using hafnium oxide, titanium oxide, aluminum oxide, etc. Additionally, the dielectric layer 126 may be formed by a CVD process or an ALD process.

An upper electrode 128 sufficiently covering the underlying structures is formed on the dielectric layer 126. The upper electrode 128 may be formed using a metal, a metal nitride or polysilicon doped with impurities. The upper electrode 128 may include a metal film, a metal nitride film or a doped polysilicon film. Alternatively, the upper electrode 128 may have a multi-layer structure that includes a doped polysilicon film and a metal film or a metal nitride film.

As described above, the lower electrode 122a is formed without a CMP process so that the time and cost for manufacturing a semiconductor device including the capacitor can be reduced. In addition, since the photoresist pattern protects the cylindrical lower electrode 122a in the process for removing the mold layer 118, damage to the lower electrode 122a is efficiently prevented. Further, the etching solution does not permeate into the contact plug 114 through the lower edge portion of the lower electrode 122a due to the photoresist pattern, thereby preventing the contact plug 114 and the lower electrode 122a from being damaged.

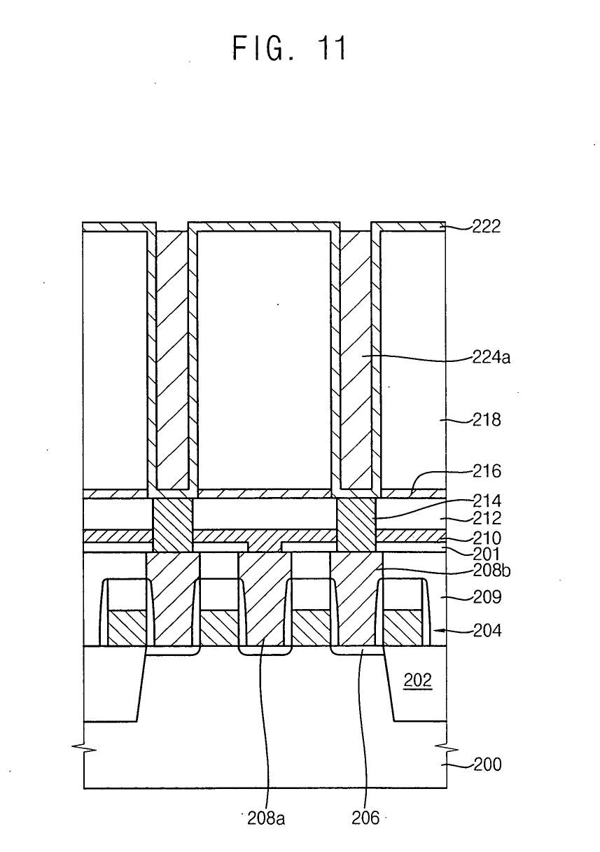

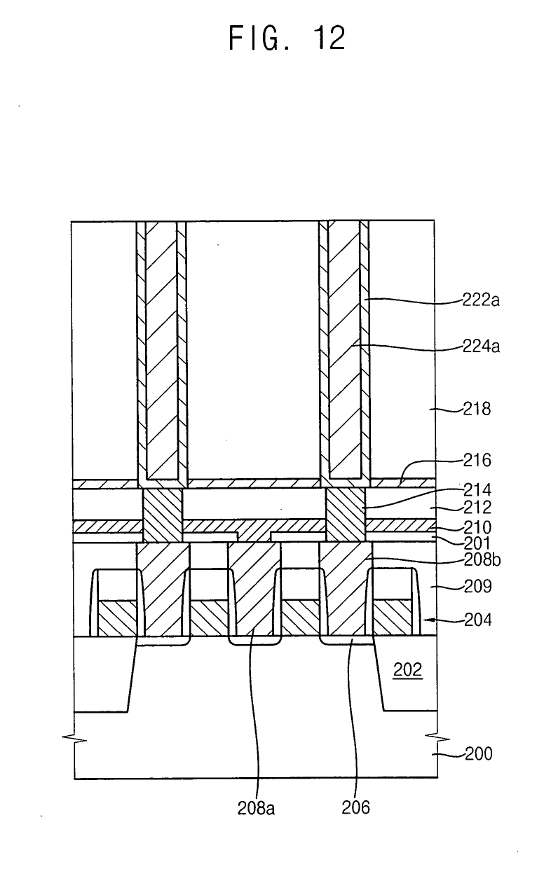

FIGS. 11 and 12 are cross-sectional views illustrating a method of manufacturing a semiconductor device according to an example embodiment of the present invention. In FIGS. 11 and 12, the method of manufacturing the semiconductor device such as a DRAM device is substantially identical to the method described with reference to FIGS. 1 to 10 except for the photoresist film 224a.

Referring to FIG. 11, an isolation layer 202 is formed on a semiconductor substrate 200 by an isolation process, for example, a shallow trench isolation (STI) process, thereby defining an active region of the substrate 200.

After gate structures 204 are formed on the substrate 200, source/drain regions 206 are formed at upper portions of the substrate 200 exposed between the gate structures 204. Each of the gate structures 204 includes a gate insulation layer pattern, a gate electrode, a gate mask and a gate spacer formed on the substrate 200. When the source/drain regions 206 are formed, transistors including the gate structures 204 and the source/drain regions 206 are completed on the substrate 200.

After a first insulating interlayer 209 is formed on the substrate 200 to cover the transistors, the first insulating interlayer 209 is partially etched to form first contact holes that expose the source/drain regions 206.

A first conductive layer is formed on the first insulating interlayer 209 to fill up the first contact holes, and then the first conductive layer is partially removed to thereby form first and second pad electrodes 208a and 208b in the first contact holes. The first pad electrode 208a is electrically contacted with a bit line 210, whereas the second pad electrode 208b is electrically connected to a capacitor.

After a second insulating interlayer 201 is formed on the first insulating interlayer 209, the first pad electrode 208a and the second pad electrode 208b, the second insulating interlayer 201 is partially etched to form a second contact hole that exposes the first pad electrode 208a.

A second conductive layer is formed on the second insulating interlayer 201 to fill up the second contact hole, and then the second conductive layer is partially etched to form a bit line 210 that makes contact with the first pad electrode 208a.

After a third insulating interlayer 212 is formed on the bit line 210, the third insulating interlayer 212 is partially etched to form a third contact hole exposing the second pad electrode 208b.

A third conductive layer is formed on the third insulating interlayer 212 to fill up the third contact hole, and then the third conductive layer is partially removed to form a contact plug 214 in the third contact hole.

An etch stop layer 216 and a mold layer 218 are sequentially formed on the third insulating interlayer 212 and the contact plug 214. Then, the mold layer 218 and the etch stop layer 216 are partially etched to form an opening that exposes the contact plug 214.

After a fourth conductive layer 222 is formed on the contact plug 214, a sidewall of the opening and the mold layer 218, a photoresist film is formed on the fourth conductive layer 222 to fill up the opening.

The photoresist film is partially removed until the fourth conductive layer 222 is exposed, thereby forming a photoresist pattern 224a in the opening. That is, a portion of the photoresist film positioned over the mold layer 218 is selectively removed to form the photoresist pattern 224a filling up the opening. The photoresist film may be partially etched by a dry etching process.

Referring to FIG. 12, the fourth conductive layer 222 is partially removed until the mold layer 218 is exposed to form the lower electrode 222a on the contact plug 214 and the sidewall of the opening. The lower electrode 222a may be formed using a dry etching process.

In one example embodiment of the present invention, the photoresist film 224 and the fourth conductive layer 222 are simultaneously etched when the fourth conductive layer 222 has an etching selectivity substantially identical to that of the photoresist film. In another example embodiment of the present invention, when the photoresist film has an etching selectivity different from that of the fourth conductive layer 222, the fourth conductive layer 222 may be partially etched after partially etching the photoresist film.

Then, the semiconductor device, for example a DRAM device, including the lower electrode 222a is completed over the substrate 200 by removing the mold layer 218 and the photoresist pattern 224a using processes substantially identical those described with reference to FIGS. 8 to 10.

According to the present invention, a lower electrode of a capacitor can be formed without a CMP process so that the time and cost for manufacturing a semiconductor device including the capacitor can be reduced. Additionally, since the etching solution does not permeate into the lower electrode and the contact plug electrically connected to the lower electrode, damage to the lower electrode and the contact plug are effectively prevented. As a result, the semiconductor device such as a DRAM device has improved electrical characteristics and reliability with greatly reduced likelihood of failure.

While the present invention has been particularly shown and described with references to example embodiments thereof, it will be understood by those skilled in the art that various changes in form and details may be made herein without departing from the spirit and scope of the present invention as defined by the appended claims.

What is claimed is:

1. A method of manufacturing a capacitor comprising:
forming a mold layer on a substrate having a contact plug, the mold layer including an opening exposing the contact plug;
forming a conductive layer on the contact plug, an inner sidewall of the opening and the mold layer;
forming a photoresist pattern that substantially fills the opening;
forming a cylindrical lower electrode by partially removing the conductive layer;
selectively removing the mold layer while preventing damage to the lower electrode, the contact plug and the substrate by the photoresist pattern;
removing the photoresist pattern;
forming a dielectric layer on the lower electrode; and
forming an upper electrode on the dielectric layer.

2. The method of claim 1, wherein the conductive layer comprises a film selected from the group consisting: of titanium film; a titanium nitride film; and a multi-layer structure that includes a titanium film and a titanium nitride film.

3. The method of claim 1, wherein the contact plug comprises a conductive material different from that of the conductive layer.

4. The method of claim 1, wherein the contact plug comprises polysilicon doped with impurities.

5. The method of claim 1, wherein forming the photoresist pattern further comprises:
forming a photoresist film on the conductive layer that substantially fills the opening;
exposing the photoresist film to a light by a blank exposure process; and
developing the photoresist film.

6. The method of claim 5, wherein the light is defocused relative to the photoresist film in the blank exposure process in order to selectively develop an upper portion of the photoresist film.

7. The method of claim 5, wherein the photoresist film comprises a coloring agent to adjust a permeability of the light.

8. The method of claim 5, further comprising thermally treating the photoresist film after forming the photoresist film.

9. The method of claim 1, wherein partially removing the conductive layer to form the lower electrode comprises performing an etch back process.

10. The method of claim 1, wherein forming the photoresist pattern further comprises:
forming a photoresist film on the conductive layer to substantially fill the opening; and
partially removing the photoresist film.

11. The method of claim 1, wherein the mold layer is removed using a wet etching solution.

12. The method of claim 1, wherein the photoresist pattern is removed by an ashing process and/or a stripping process.

13. The method of claim 1, prior to forming the mold layer, further comprising forming an etch stop layer on the substrate.

14. The method of claim 1, wherein the conductive layer is formed by a process selected from the group consisting of: a chemical vapor deposition (CVD) process; a cyclic CVD process and an atomic layer deposition (ALD) process.

15. A method of manufacturing a semiconductor device, the method comprising:
forming a transistor on a substrate;
forming a first insulating interlayer on the substrate, the first insulating interlayer including a first pad electrode and a second pad electrode electrically connected to source/drain regions of the transistor;
forming a second insulating interlayer on the first insulating interlayer, the second insulating interlayer including a bit line electrically connected to the first pad electrode;
forming a third insulating interlayer on the second insulating interlayer, the third insulating interlayer including a contact plug electrically connected to the second pad electrode;
forming a mold layer on the third insulating interlayer, the mold layer including an opening exposing the contact plug;
forming a conductive layer on the contact plug, an inner sidewall of the opening and the mold layer;
forming a photoresist pattern that substantially fills the opening;
forming a cylindrical lower electrode by partially removing the conductive layer;
selectively removing the mold layer while preventing damage to the lower electrode and underlying structures by the photoresist pattern;
removing the photoresist pattern;
forming a dielectric layer on the lower electrode and the third insulating interlayer; and
forming an upper electrode on the dielectric layer.

16. The method of claim 15, wherein the conductive layer comprises a film selected from the group consisting of: a titanium film; a titanium nitride film; and a multi-layer structure that includes a titanium film and a titanium nitride film.

17. The method of claim 15, wherein the contact plug comprises polysilicon doped with impurities.

18. The method of claim 15, wherein the mold layer is removed using a wet etching solution.

19. The method of claim 15, wherein the photoresist pattern is removed by an ashing process and/or a stripping process.

20. The method of claim 15, prior to forming the mold layer, further comprising forming an etch stop layer on the third insulating interlayer.
